(19) United States
(12) Patent Application Publication
(10) Pub. No.: US 2013/0135820 A1
(43) Pub. Date: May 30, 2013

(54) SERVER RACK SYSTEM FOR MANAGING FAN ROTATION SPEED

(71) Applicant: Hao-Hao Wang, Shanghai City (CN)

(72) Inventor: Hao-Hao Wang, Shanghai City (CN)

(73) Assignee: INVENTEC CORPORATION, Taipei City (TW)

(21) Appl. No.: 13/396,143

(22) Filed: Feb. 14, 2012

(30) Foreign Application Priority Data
Nov. 28, 2011 (CN) 201110385461.1

(51) Int. Cl. H05K 7/20

(52) U.S. Cl. 361/679.48

(57) ABSTRACT

A server rack system for managing a fan rotation speed is provided, and the system includes: at least one first network switch, multiple servers, at least one fan unit, at least one fan control unit and an Integrated Management Module (IMM). Each of the servers has at least one temperature detecting element, and the temperature detecting element detects and obtains temperature information related to multiple servers, in which the temperature information is uploaded to a management network. The fan control unit is connected to the fan unit. The IMM has a management network port connected to the management network, obtains the temperature information through the management network, then generates a control command according to the temperature information, and transmits the control command to the fan control unit through the management network. The fan control unit adjusts the rotation speed of the fan unit according to the control command.

### CROSS-REFERENCE TO RELATED APPLICATION

This application claims the priority benefit of China application Ser. No. 201110385461.1, filed on Nov. 28, 2011. The entirety of the above-mentioned patent application is hereby incorporated by reference herein and made a part of this specification.

### BACKGROUND OF THE INVENTION

1. Field of the Invention

The present invention relates to a server rack system, and more particularly to a server rack system for managing a fan rotation speed.

2. Description of Related Art

A server has a high computing capability, and therefore is a core computer serving computers in a network system. The server is the core computer serving the computers in the network system, is capable of providing functions such as disc and printing service required by network users, and meanwhile also enables clients to share resources in a network environment with each other.

In terms of appearances, servers are basically divided into three types, including a pedestal server, a rack server and a blade server. The rack server is a pedestal server with an optimized structure, and is designed for the purpose of reducing the space occupied by the server. A width of the rack server is usually 19 inches, and a height thereof is in a unit of U (1 U=1.75 inches). A server rack is taken as an example herein. The server rack is a server with the appearance designed according to a uniform standard, and is uniformly used in coordination with a cabinet. The rack is a tower server with an optimized structure, and is designed for the purpose of reducing the space occupied by the server as much as possible. Many professional network devices, such as the switch, router and hardware firewall, adopt the rack structure, and are mostly flat like a drawer. A width of the server rack is 19 inches, and a height thereof is in the unit of U (1 U=1.75 inches=44.45 mm), and several standard servers of 1 U, 2 U, 3 U, 4 U, 5 U and 7 U are available usually.

A basic architecture of the server is generally the same as that of a common personal computer, and includes members such as a Central Processing Unit (CPU), a memory, and input/output devices, which are connected inside the server through a bus. The CPU and the memory are connected through a north bridge chip, and the input/output devices are connected through a south bridge chip. However, when the server operates, the temperature of the entire system rises. If it is required that all members operate normally, a proper heat dissipation mechanism is needed. However, when an error occurs to rotation speed configuration of a fan unit that is responsible for heat dissipation, quality of service of the server is affected, and situations such as a startup failure, a setting value error or system instability may occur.

### SUMMARY OF THE INVENTION

Accordingly, the present invention is directed to a server rack system for managing a fan rotation speed, in which an Integrated Management Module (IMM) generates a control command according to temperature information of a server to adjust the rotation speed of the fan unit.

The present invention provides a server rack system for managing a fan rotation speed, and the system includes: at least one first network switch, multiple servers, at least one fan unit, at least one fan control unit and an IMM. The first network switch is coupled to a management network. Among the multiple servers, each server at least has one temperature detecting element. The temperature detecting elements detect and obtain temperature information related to the multiple servers, and the temperature information is uploaded to the management network. The fan unit is used to facilitate heat dissipation of the rack system. The fan control unit is connected to the fan unit, and the fan control unit has a management network port connected to the management network. The IMM has a management network port connected to the management network, obtains the temperature information through the management network, then generates a control command according to the temperature information, and transmits the control command to the fan control unit through the management network. The fan control unit adjusts the rotation speed of the fan unit according to the control command.

In an embodiment of the present invention, each of the servers has a respective Baseboard Management Controller (BMC), and the BMC has a respective management network port connected to the management network. Among the servers, the BMC collects the temperature information related to the server detected by the temperature detecting element, and uploads the temperature information to the management network through the management network port.

In an embodiment of the present invention, the IMM computes a desired rotation speed of the fan unit according to the temperature information, in which the control command includes desired rotation speed information, and transmits the desired rotation speed information to the fan control unit through the management network. The fan control unit adjusts the rotation speed of the fan unit according to the desired rotation speed information.

In an embodiment of the present invention, each of the fan units corresponds to multiple servers, and the IMM computes a desired rotation speed of the fan unit according to the temperature information corresponding to the server.

In an embodiment of the present invention, the IMM is preset with an information table including a temperature-rotation speed correspondence relationship, and the IMM obtains a corresponding desired rotation speed by querying the information table according to the temperature information.

In an embodiment of the present invention, the control command includes a piece of request information. The fan control unit acquires from the management network the temperature information corresponding to the fan unit controlled by the fan control unit according to the request information, and computes a desired rotation speed of the fan unit. The fan control unit adjusts the rotation speed of the fan unit according to the desired rotation speed.

In an embodiment of the present invention, the fan control unit is preset with an information table including a temperature-rotation speed correspondence relationship, and the fan control unit obtains a corresponding desired rotation speed by querying the information table according to the temperature information.

In an embodiment of the present invention, the fan control unit receives the control command of the IMM from the management network through the management network port on the fan control unit, and outputs a modulation signal to the corresponding fan unit according to the control command, to adjust the rotation speed of the fan unit.

In an embodiment of the present invention, the fan control unit collects a rotation signal of the corresponding fan unit through a signal line, and computes a working rotation speed of the fan unit according to the rotation signal.

In an embodiment of the present invention, the fan control unit further sends the working rotation speed of the fan unit to the IMM through the management network.

In an embodiment of the present invention, the IMM computes a desired rotation speed of the fan unit according to the temperature information, and compares the desired rotation speed with the working rotation speed, to generate the control command.

In an embodiment of the present invention, one fan control unit controls multiple fan units, and the fan control unit respectively sends a modulation signal to each of the fan units, so that each of the fan units runs with a respective rotation speed.

In an embodiment of the present invention, the IMM acquires a version number of firmware of the fan control unit through the management network, to judge whether the firmware is of the latest version, and if the firmware is not of the latest version, updates the firmware of the fan control unit.

In an embodiment of the present invention, the IMM stores latest-version firmware of the fan control unit, and when the firmware of the fan control unit is not of the latest version, the IMM updates the latest-version firmware into the fan control unit through the management network.

In an embodiment of the present invention, the first network switch has multiple local area network ports. The local area network ports of the first network switch are connected to the server or the fan control unit located at a corresponding position according to a port device position table, and the IMM knows the position of the server or the fan control unit in a rack according to the port device position table.

In an embodiment of the present invention, the fan control unit has a Media Access Control (MAC) address. The IMM stores an asset correspondence table. The asset correspondence table stores asset numbers and the MAC address of the fan control unit. The IMM acquires the MAC address of the fan control unit through the management network, and queries the asset correspondence table according to the acquired address, to obtain a corresponding asset number.

In an embodiment of the present invention, each of the servers has a respective service network port, and the server rack system further includes a second network switch. The second network switch is connected to the service network port of the server, in which the server provides services to a service network through the second network switch.

Based on the above, the present invention provides a server rack system for managing a fan rotation speed, in which an IMM generates a control command according to temperature information of a server, and then a fan control unit adjusts the rotation speed of the fan unit based on the control command.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a functional block diagram of a server rack system for managing a fan rotation speed according to an embodiment of the present invention.

FIG. 1B is a functional block diagram of a server rack system for managing a fan rotation speed according to another embodiment of the present invention.

FIG. 2 is a flow chart of an operating method of a server rack system for managing a fan rotation speed according to an embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

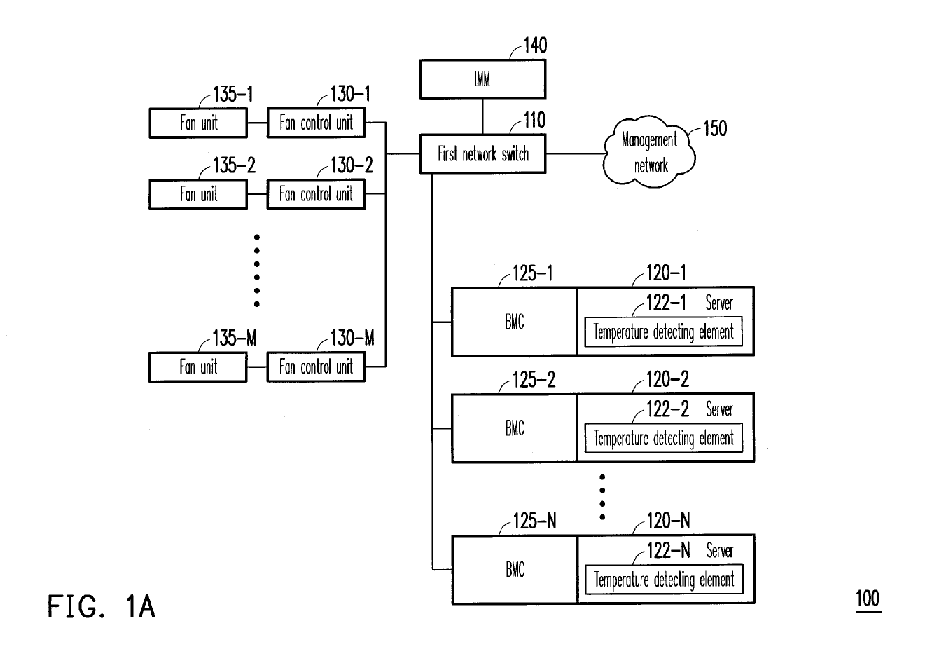

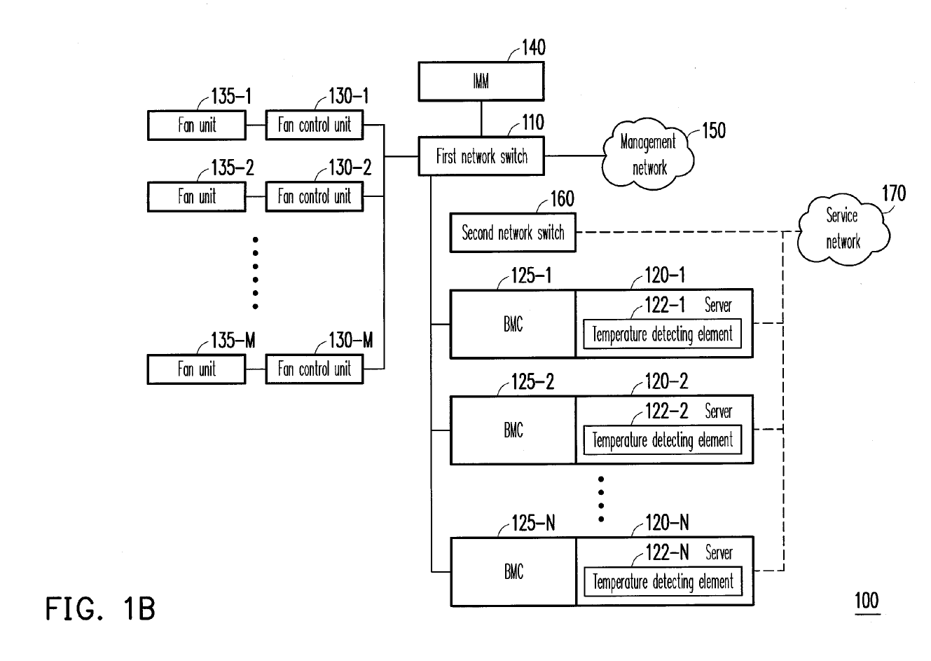

FIG. 1A is a functional block diagram of a server rack system for managing a fan rotation speed according to an embodiment of the present invention. A server rack system 100 includes a first network switch 110, servers 120-1 to 120-N, BMCs 125-1 to 125-N, an IMM 140, a management network 150, fan control units 130-1 to 130-M and corresponding fan units 135-1 to 135-M. N and M are positive integers greater than 1. The first network switch 110 is coupled to the management network 150, and the management network 150 is a network resource provided by an Internet Service Provider (ISP). The servers 120-1 to 120-N have the respective BMCs 125-1 to 125-N, and each of the BMCs 125-1 to 125-N has a management network port connected to the management network 150. In addition, the servers 120-1 to 120-N have respective temperature detecting elements 122-1 to 122-N for detecting temperature information of the corresponding servers. The BMCs 125-1 to 125-N collect the temperature information detected by the temperature detecting elements 122-1 to 122-N, and upload the temperature information to the management network 150 through the management network port, in which the BMCs 125-1 to 125-N may also be replaced by other chip groups that are capable of collecting temperature information and have network ports. The fan units 135-1 to 135-M facilitate heat dissipation of the server rack system 100. The fan control units 130-1 to 130-M are connected to the fan units 135-1 to 135-M, and each of the fan control units 130-1 to 130-M has a respective management network port and is connected to the management network 150 through the first network switch 110. The IMM 140 has a management network port connected to the management network 150, and the IMM 140 is connected to the first network switch 110, and obtains the temperature information through the management network 150.

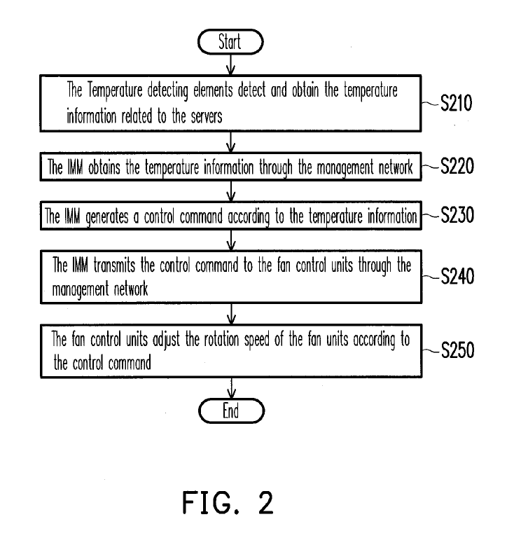

FIG. 2 is a flow chart of an operating method of a server rack system for managing a fan rotation speed according to an embodiment of the present invention. First, the temperature detecting elements 122-1 to 122-N detect and obtain the temperature information related to the servers 120-1 to 120-N (Step S210), and after the temperature information is obtained, the BMCs 125-1 to 125-N collect the temperature information detected by the temperature detecting elements 122-1 to 122-N, and upload the temperature information to the management network 150 through the management network port. Then, the IMM 140 obtains the temperature information through the management network 150 (Step S220).

The IMM 140 generates a control command according to the temperature information (Step S230). In an embodiment of the present invention, the IMM 140 computes a desired rotation speed of the fan units 135-1 to 135-M according to the temperature information. The control command includes desired rotation speed information, and the desired rotation speed information is transmitted to the fan control units 130-1 to 130-M through the management network 150. The fan control units 130-1 to 130-M adjust the rotation speed of the fan units 135-1 to 135-M according to the desired rotation speed information.

In other embodiments of the present invention, each of the fan units 135-1 to 135-M may correspond to multiple servers 120-1 to 120-N. The IMM 140 computes a desired rotation speed of the fan units 135-1 to 135-M according to the temperature information corresponding to each of the servers 120-1 to 120-N.

In other embodiments of the present invention, the IMM 140 is preset with an information table including a temperature-rotation speed correspondence relationship, and the IMM 140 obtains a corresponding desired rotation speed by querying the information table according to the temperature information.

In other embodiments of the present invention, the control command includes a piece of request information. The fan control units 130-1 to 130-M acquire from the management network 150 the temperature information corresponding to the fan units 135-1 to 135-M controlled by the fan control units 130-1 to 130-M according to the request information, and compute a desired rotation speed of the fan units 135-1 to 135-M. The fan control units 130-1 to 130-M adjust the rotation speed of the fan units 135-1 to 135-M according to the computed desired rotation speed.

In other embodiments of the present invention, the fan control units 130-1 to 130-M may also be preset with an information table including a temperature-rotation speed correspondence relationship, and the fan control units 130-1 to 130-M obtain a corresponding desired rotation speed by querying the information table according to the temperature information.

In other embodiments of the present invention, the fan control units 130-1 to 130-M may also first compute a working rotation speed of the fan units 135-1 to 135-M. An implementation method thereof is that the fan control units 130-1 to 130-M collect a rotation signal of the corresponding fan units 135-1 to 135-M through a signal line, and compute a working rotation speed of the fan units 135-1 to 135-M according to the rotation signal. Then, the fan control units 130-1 to 130-M further send the working rotation speed of the fan units 135-1 to 135-M to the IMM 140 through the management network 150. The IMM 140 computes a desired rotation speed of the fan units 135-1 to 135-M according to the temperature information, and compares the desired rotation speed with the working rotation speed, to generate the control command.

The IMM 140 transmits the control command to the fan control units 130-1 to 130-M through the management network 150 (Step S240). The fan control units 130-1 to 130-M adjust the rotation speed of the fan units 135-1 to 135-M according to the control command (Step S250). The fan control units 130-1 to 130-M receive the control command of the IMM 140 from the management network through the management network ports on the fan control units 130-1 to 130-M, and output a modulation signal to the corresponding fan units 135-1 to 135-M according to the control command, to adjust the rotation speed of the fan units 135-1 to 135-M.

In other embodiments of the present invention, multiple fan units 135-1 to 135-M may also be controlled by one fan control unit (for example, 130-1), and the fan control unit 130-1 respectively sends a modulation signal to each of the fan units 135-1 to 135-M, so that each of the fan units 135-1 to 135-M runs with a respective rotation speed.

FIG. 1B is a functional block diagram of a server rack system for managing a fan rotation speed according to another embodiment of the present invention. In the embodiment described in FIG. 1B, the server rack system further includes a second network switch 160, and each of the servers 120-1 to 120-N has a respective service network port. The second network switch 160 is connected to the service network ports of the servers 120-1 to 120-N, in which the servers 120-1 to 120-N provide services to a service network 170 through the second network switch 160.

In other embodiments of the present invention, the IMM 140 acquires a version number of firmware of the fan control units 130-1 to 130-M through the management network 150, to judge whether the firmware is of the latest version, and if the firmware is not of the latest version, updates the firmware of the fan control units 130-1 to 130-M.

In other embodiments of the present invention, the IMM 140 stores latest-version firmware of the fan control units 130-1 to 130-M, and when the firmware of the fan control units 130-1 to 130-M is not of the latest version, the IMM 140 updates the latest-version firmware into the fan control units 130-1 to 130-M through the management network 150.

In other embodiments of the present invention, the first network switch 110 has multiple local area network ports. The local area network ports of the first network switch 110 are connected to multiple servers 120-1 to 120-N or multiple fan control units 130-1 to 130-M located at corresponding positions according to a port device position table, and the IMM 140 knows the positions of multiple servers 120-1 to 120-N or multiple fan control units 130-1 to 130-M in a rack according to the port device position table.

In other embodiments of the present invention, the fan control units 130-1 to 130-M have an MAC address. The IMM 140 stores an asset correspondence table. The asset correspondence table stores asset numbers and the MAC address of the fan control units 130-1 to 130-M. The IMM 140 acquires the MAC address of the fan control units 130-1 to 130-M through the management network 150, and queries the asset correspondence table according to the acquired address, to obtain a corresponding asset number.

In conclusion, the present invention provides a server rack system for managing a fan rotation speed. An IMM in the server rack system generates a control command according to temperature information of each of the servers, and uploads the control command to a management network. The fan control unit obtains the control command through the management network, to adjust the fan unit to a desired rotation speed. Therefore, the implementation method of the present invention may achieve the efficient management over the fan units through the network without increasing hardware costs.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A server rack system, comprising:
at least one first network switch, wherein the first network switch is coupled to a management network;
multiple servers, wherein the server at least comprises one temperature detecting element, the temperature detecting element detects and obtains temperature information related to the server, and the temperature information is uploaded to the management network;
at least one fan unit, used for facilitating heat dissipation of the rack system;
at least one fan control unit, connected to the fan unit, wherein the fan control unit comprises a management network port connected to the management network; and
an Integrated Management Module (IMM), wherein the IMM comprises a management network port connected to the management network, and the IMM obtains the temperature information through the management network,
wherein the IMM generates a control command according to the temperature information, the IMM transmits the control command to the fan control unit through the management network, and the fan control unit adjusts the rotation speed of the fan unit according to the control command.

2. The server rack system according to claim 1, wherein each of the servers comprises a respective Baseboard Management Controller (BMC), the BMC comprises a respective management network port connected to the management network, and in each of the servers, the BMC collects the temperature information related to the server detected by the temperature detecting element, and uploads the temperature information to the management network through the management network port.

3. The server rack system according to claim 1, wherein the IMM computes a desired rotation speed of the fan unit according to the temperature information, the control command comprising desired rotation speed information, and transmits the desired rotation speed information to the fan control unit through the management network, and the fan control unit adjusts the rotation speed of the fan unit according to the desired rotation speed information.

4. The server rack system according to claim 3, wherein each fan unit corresponds to multiple servers, and the IMM computes the desired rotation speed of the fan unit according to the temperature information corresponding to the server.

5. The server rack system according to claim 3, wherein the IMM is preset with an information table comprising a temperature-rotation speed correspondence relationship, and the IMM obtains a corresponding desired rotation speed by querying the information table according to the temperature information.

6. The server rack system according to claim 1, wherein the control command comprises a piece of request information, the fan control unit acquires from the management network the temperature information corresponding to the fan unit controlled by the fan control unit according to the request information, and computes a desired rotation speed of the fan unit, and the fan control unit adjusts the rotation speed of the fan unit according to the desired rotation speed.

7. The server rack system according to claim 6, wherein the fan control unit is preset with an information table comprising a temperature-rotation speed correspondence relationship, and the fan control unit obtains a corresponding desired rotation speed by querying the information table according to the temperature information.

8. The server rack system according to claim 1, wherein the fan control unit receives the control command of the IMM from the management network through the management network port on the fan control unit, and outputs a modulation signal to the corresponding fan unit according to the control command, to adjust the rotation speed of the fan unit.

9. The server rack system according to claim 8, wherein the fan control unit collects a rotation signal of the corresponding fan unit through a signal line, and computes a working rotation speed of the fan unit according to the rotation signal.

10. The server rack system according to claim 9, wherein the fan control unit further sends the working rotation speed of the fan unit to the IMM through the management network.

11. The server rack system according to claim 10, wherein the IMM computes a desired rotation speed of the fan unit according to the temperature information, and compares the desired rotation speed with the working rotation speed, to generate the control command.

12. The server rack system according to claim 8, wherein one fan control unit controls multiple fan units, and the fan control unit respectively sends a modulation signal to each of the fan units, so that each of the fan units runs with a respective rotation speed.

13. The server rack system according to claim 1, wherein the IMM acquires a version number of firmware of the fan control unit through the management network, to judge whether the firmware is of the latest version, and if the firmware is not of the latest version, updates the firmware of the fan control unit.

14. The server rack system according to claim 13, wherein the IMM stores latest-version firmware of the fan control unit, and when the firmware of the fan control unit is not of the latest version, the IMM updates the latest-version firmware into the fan control unit through the management network.

15. The server rack system according to claim 1, wherein the first network switch comprises multiple local area network ports, the local area network ports of the first network switch are connected to the server or the fan control unit located at a corresponding position according to a port device position table, and the IMM knows the position of the server or the fan control unit in a rack according to the port device position table.

16. The server rack system according to claim 1, wherein the fan control unit comprises a Media Access Control (MAC) address, the IMM stores an asset correspondence table, and the asset correspondence table stores asset numbers and the MAC address of the fan control unit; and
the IMM acquires the MAC address of the fan control unit through the management network, and queries the asset correspondence table according to the acquired address, to obtain a corresponding asset number.

17. The server rack system according to claim 1, wherein each of the servers respectively comprises a service network port, and the server rack system further comprises:
a second network switch, connected to the service network port of the server, wherein the server provides services to a service network through the second network switch.
